(19) United States
(12) Patent Application Publication
(10) Pub. No.: US 2021/0043473 A1
(43) Pub. Date: Feb. 11, 2021

(54) EDGE TRIMMING APPARATUS

(71) Applicant: DISCO CORPORATION, Tokyo (JP)

(72) Inventors: Kokichi MINATO, Tokyo (JP); Paul Vincent ATENDIDO, Tokyo (JP); Takeshi KITAURA, Tokyo (JP)

(21) Appl. No.: 16/941,941

(22) Filed: Jul. 29, 2020

(30) Foreign Application Priority Data
Aug. 6, 2019 (JP) 2019-144404

(51) Int. Cl. H01L 21/67

(52) U.S. Cl. CPC H01L 21/67092; H01L 21/67046; H01L 21/67051

(57) ABSTRACT

An edge trimming apparatus includes a chuck table that causes a ring-shaped groove with an outer diameter smaller than the outer diameter of a wafer to communicate with a suction source to hold under suction a lower surface of the wafer by the ring-shaped groove, a cutting unit that rotates a cutting blade and annularly cuts a circumferential part of the wafer held by the chuck table, and a cleaning unit that cleans a region outside the ring-shaped groove in the upper surface of the table and the upper surface of the table including the ring-shaped groove. The cleaning unit is positioned to the region outside the ring-shaped groove in the upper surface of the table and the upper surface of the chuck table including the ring-shaped groove, and the chuck table is rotated to clean the ring-shaped groove and the upper surface.

### BACKGROUND OF THE INVENTION

### Field of the Invention

The present invention relates to an edge trimming apparatus that executes trimming of the circumferential part of a wafer.

### Description of the Related Art

When a wafer is ground by a grinding abrasive stone and the thickness thereof is made smaller, there is a problem that a chamfered part at the circumference of the wafer becomes a sharp edge and the wafer breaks with the sharp edge being the point of origin. Thus, there is an edge trimming apparatus for removing the circumferential part of a wafer before grinding (for example, refer to Japanese Patent Laid-open No. 2010-165802 or Japanese Patent Laid-open No. 2017-004989).

The edge trimming apparatus brings an abrasive stone into contact with the circumferential part of a wafer held by a holding surface of a chuck table and rotates the wafer to remove the circumferential part. If processing dust discharged due to this edge trimming processing enters a gap between the lower surface of the wafer and the holding surface of the chuck table and adheres on the holding surface, the height of the lower surface of the wafer held by the holding surface does not become constant. For this reason, for example, in the case of completely cutting a chamfered part of a bonded wafer obtained by bonding a wafer to a substrate by an adhesive as in a method disclosed in Japanese Patent Laid-open No. 2017-004989, there is a problem that the adhesive existing on the bonded surface adheres to a cutting blade and the cutting processing becomes impossible.

In order to solve this problem, a ring-shaped groove with an outer diameter slightly smaller than the outer diameter of the wafer is formed in a flat upper surface of the chuck table. The ring-shaped groove is made to communicate with a suction source and the wafer is held under suction by the ring-shaped groove. In addition, most part of the upper surface of the chuck table is formed as a sliding surface to suppress adhesion of processing dust.

### SUMMARY OF THE INVENTION

However, processing dust enters a gap between the chuck table and the wafer from the circumferential edge of the wafer and the processing dust adheres to the vicinity of the ring-shaped groove in the upper surface of the chuck table in some cases, which causes a problem.

Thus, an object of the present invention is to provide an edge trimming apparatus that can hold a wafer by a chuck table with a holding surface to which processing dust is not adhered.

In accordance with an aspect of the present invention, there is provided an edge trimming apparatus including a chuck table that has a ring-shaped groove with an outer diameter smaller than the outer diameter of a wafer and causes the ring-shaped groove to communicate with a suction source to hold under suction a lower surface of the wafer by the ring-shaped groove, a table rotation mechanism that rotates the chuck table, a cutting unit that rotates a spindle on which a cutting blade is mounted and annularly cuts a circumferential part of the wafer held by the chuck table, and a cleaning unit that cleans a region outside the ring-shaped groove in an upper surface of the chuck table and the upper surface of the chuck table including the ring-shaped groove. The cleaning unit is positioned to the region outside the ring-shaped groove in the upper surface of the chuck table and the upper surface of the chuck table including the ring-shaped groove, and the chuck table is rotated by the table rotation mechanism, to clean the region outside the ring-shaped groove in the upper surface of the chuck table and the upper surface of the chuck table including the ring-shaped groove.

Preferably, the edge trimming apparatus further includes a horizontal movement mechanism that moves the cutting unit in the center axis direction of the spindle. The cutting unit includes a spindle unit that rotates the spindle to which a mount on which the cutting blade is mounted is coupled and a blade cover that surrounds the mount and the cutting blade. The cleaning unit includes a cleaning nozzle that is mounted on the blade cover and jets high-pressure water in a downward direction. A landing area of the high-pressure water jetted from the cleaning nozzle is positioned to the region outside the ring-shaped groove in the upper surface of the chuck table and the upper surface of the chuck table including the ring-shaped groove by the horizontal movement mechanism, and cleaning is executed.

Preferably, the cleaning unit includes a sponge and a nozzle for sponge that supplies cleaning water to the sponge. The sponge is positioned to the region outside the ring-shaped groove in the upper surface of the chuck table and the upper surface of the chuck table including the ring-shaped groove, and cleaning is executed by the sponge to which the cleaning water is supplied from the nozzle for sponge.

According to the present invention, the wafer can be flatly held by the chuck table that has been cleaned and has an upper surface to which processing dust is not adhered. Therefore, the depth of the recess formed at the circumferential edge of the wafer by edge trimming processing can be made constant. Moreover, because the inside of the ring-shaped groove of the chuck table can be cleaned, it becomes possible to prevent the lowering of the suction force of the chuck table that possibly occurs due to clogging of the ring-shaped groove with processing dust.

Further, for example, in the edge trimming apparatus including two cutting units opposed to each other, each cutting unit can include the cleaning nozzle as the cleaning unit, and the cleaning areas of the respective cleaning nozzles can be made different to change the role in the cleaning. For example, one cleaning nozzle is used as a nozzle dedicated to intensive cleaning for the region immediately outside the ring-shaped groove in the upper surface of the chuck table and is caused to jet high-pressure water in a circular column shape. Meanwhile, the other cleaning nozzle is used as a nozzle dedicated to cleaning of a wide range mainly for the upper surface of the chuck table and the ring-shaped groove and is caused to jet the high-pressure water in a fan shape. This enables cleaning of the region outside the ring-shaped groove in the upper surface of the chuck table and the upper surface of the chuck table including the ring-shaped groove more efficiently.

Further, when the cleaning unit includes the sponge and the nozzle for sponge that supplies the cleaning water to the sponge, the sponge is positioned to the region outside the ring-shaped groove in the upper surface of the chuck table and the upper surface of the chuck table including the ring-shaped groove, and cleaning is executed by the sponge to which the cleaning water is supplied from the nozzle for sponge. Accordingly, the wafer can be flatly held by the chuck table that has been cleaned and has an upper surface to which processing dust is not adhered. Therefore, the depth of the recess formed at the circumferential edge of the wafer by edge trimming processing can be made constant. Furthermore, because the inside of the ring-shaped groove can be cleaned, it becomes possible to prevent the lowering of the suction force of the chuck table.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view illustrating one example of an edge trimming apparatus in which a cleaning unit includes a cleaning nozzle;

FIG. 2 is a sectional view illustrating one example of the structure of a chuck table;

FIG. 3 is a perspective view illustrating one example of a first cutting unit and the cleaning unit including the cleaning nozzle;

FIG. 4 is a schematic plan view for explaining the structure and disposing position of a shower nozzle, two cutting water nozzles, a pair of blade cooling nozzles, and the cleaning nozzle of the first cutting unit;

FIG. 5 is a schematic plan view for explaining the structure and disposing position of the shower nozzle, the two cutting water nozzles, the pair of blade cooling nozzles, and the cleaning nozzle of a second cutting unit;

FIG. 6 is a sectional view for explaining the state in which a region outside a ring-shaped groove in the upper surface (holding surface) of the chuck table and the upper surface of the chuck table including the ring-shaped groove are being cleaned by the cleaning units including the cleaning nozzles while the chuck table is rotated;

FIG. 7 is a sectional view for explaining the case in which a bonded wafer is held under suction by the chuck table in which the region outside the ring-shaped groove in the upper surface and the upper surface including the ring-shaped groove have been cleaned and edge trimming of a chamfered part of a wafer is executed by the first cutting unit;

FIG. 8 is a perspective view illustrating one example of an edge trimming apparatus in which a cleaning unit includes a sponge; and

FIG. 9 is a sectional view for explaining the state in which the region outside the ring-shaped groove in the upper surface of the chuck table and the upper surface of the chuck table including the ring-shaped groove are being cleaned by the cleaning unit including the sponge while the chuck table is rotated.

### DETAILED DESCRIPTION OF THE PREFERRED EMBODIMENTS

### First Embodiment

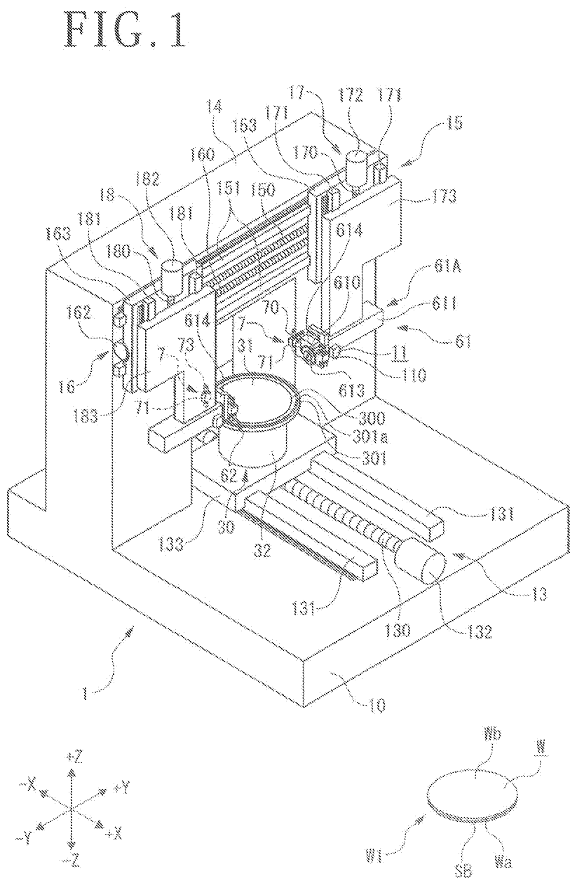

An edge trimming apparatus 1 illustrated in FIG. 1 according to the present invention (hereinafter, referred to as the edge trimming apparatus 1 of a first embodiment) is an apparatus that can execute edge trimming of a wafer W held by a chuck table 30 by a first cutting unit 61 or a second cutting unit 62 including a cutting blade 613 that rotates. The edge trimming apparatus 1 is not limited to an apparatus of a type that enables dual cutting (two-axis simultaneous cutting) of the wafer W.

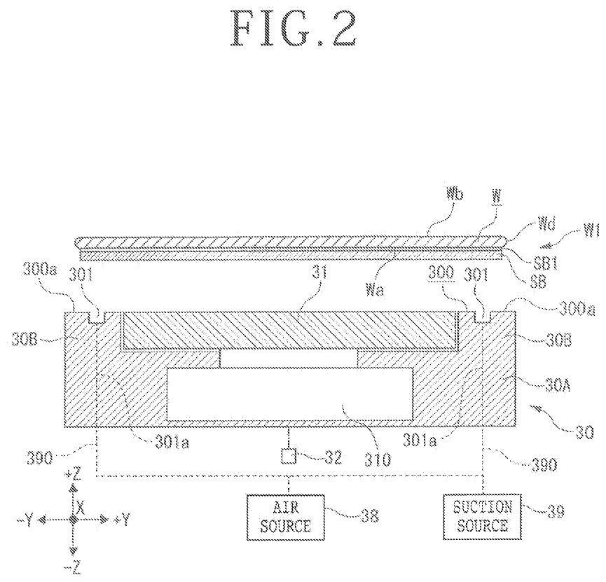

For example, the wafer W illustrated in FIG. 1 is a semiconductor wafer that includes silicon as the base material and has a circular shape as the outer shape and, on a front surface Wa thereof, unillustrated devices, such as integrated circuits (ICs), are each formed in a respective one of regions marked out in a lattice manner. In the wafer W, chamfering processing has been executed for the circumferential edge, and a chamfered part Wd (see FIG. 2) whose section has a substantially circular arc shape is formed. The wafer W may be composed of, besides silicon, gallium arsenide, sapphire, gallium nitride, ceramic, resin, silicon carbide, or the like, and the devices do not need to be formed.

As illustrated in FIG. 2, the wafer W is what is generally called a bonded wafer W1, for example. Specifically, for the circular wafer W, bonded to the front surface Wa oriented downward in FIG. 2 is a substrate SB (support substrate) with substantially the same diameter by an adhesive SB1 or the like. Thus, by treating the wafer W and the substrate SB as a monolithic component and executing processing, the handling property of the wafer W is improved, and warpage and breakage of the wafer W at the time of the processing can be prevented. The center of the wafer W substantially corresponds with the center of the substrate SB.

On a base 10 of the edge trimming apparatus 1, a cutting feed mechanism 13 that moves the chuck table 30 in an X-axis direction is disposed. The cutting feed mechanism 13 includes a ball screw 130 having the center axis that extends in the X-axis direction, a pair of guide rails 131 disposed in parallel to the ball screw 130, a motor 132 that rotates the ball screw 130, and a movable plate 133 that has an internal nut screwed to the ball screw 130 and has a bottom part in slide contact with the guide rails 131. Further, when the motor 132 rotates the ball screw 130, the movable plate 133 is guided by the guide rails 131 and moves in the X-axis direction in association with this, so that cutting feeding of the chuck table 30 that is disposed on the movable plate 133 and holds under suction the bonded wafer W1 is executed in the X-axis direction in association with the movement of the movable plate 133.

For example, the chuck table 30 illustrated in FIG. 2 includes a base part 30A whose outer shape is a circular shape in plan view, and a ring-shaped projecting part 30B that is formed of a solid component that is ceramic or an alloy such as stainless steel, for example, and has a circular ring shape in plan view is disposed upright on the upper surface of the base part 30A. The upper surface of the ring-shaped projecting part 30B is a smooth holding surface 300 that holds under suction the circumferential-side region of the lower surface of the substrate SB stuck to the front surface Wa of the wafer W.

For example, a ring-shaped groove 301 with an outer diameter smaller than the outer diameter of the substrate SB is formed at a substantially middle position of the circular-ring-shaped holding surface 300 in the ring width. Further, in the groove bottom of the ring-shaped groove 301, plural suction holes 301a are formed with the intermediary of equal intervals in the circumferential direction in such a manner as to penetrate the ring-shaped projecting part 30B and the base part 30A in the thickness direction (Z-axis direction). A suction flow path 390 such as a resin tube or metal pipe communicates with the lower end side of each suction hole 301a, and the suction flow paths 390 are connected to a suction source 39 such as a vacuum generating apparatus or an ejector mechanism. Here, the region outside the ring-shaped groove 301 in the holding surface 300, which is the upper surface 300 of the ring-shaped projecting part 30B of the chuck table 30, is defined as a region 300a.

An air source 38 including a compressor or the like that supplies air to the holding surface 300 of the chuck table 30 is connected to each suction hole 301a. For example, when the bonded wafer W1 is intended to be carried out from the chuck table 30 through releasing the suction and holding of the bonded wafer W1 by the chuck table 30, the air source 38 supplies compressed air to the suction holes 301a. As a result, by the air ejected from the suction holes 301a onto the holding surface 300, the vacuum suction force that remains between the holding surface 300 and the bonded wafer W1 is eliminated, and a state in which the bonded wafer W1 can be gripped by a clamp or the like and be removed from the holding surface 300 can be realized.

A rising-lowering table 31 with a circular plate shape in plan view is disposed in a recess-shaped space formed by the upper surface of the base part 30A and the inside surface of the ring-shaped projecting part 30B. The upper surface of the rising-lowering table 31 is a smooth surface formed of a solid component or the like. Further, the rising-lowering table 31 can move up and down in the Z-axis direction by an air cylinder 310 incorporated in the base part 30A. The air cylinder 310 may be an electric cylinder. For example, the upper surface of the rising-lowering table 31 in the state of not being raised is flush with the holding surface 300 of the ring-shaped projecting part 30B.

For example, when the bonded wafer W1 is carried out from the holding surface 300 after edge trimming processing is executed for the wafer W stuck to the substrate SB held by the holding surface 300, the rising-lowering table 31 lifts up the bonded wafer W1 to the upper side relative to the holding surface 300 to allow unillustrated conveying means to execute edge clamping of the circumferential edge of the substrate SB.

As illustrated in FIG. 1, the chuck table 30 is enabled to rotate by a table rotation mechanism 32 including a motor disposed below the chuck table 30, a rotating shaft whose axis direction is the Z-axis direction (vertical direction), and so forth.

On the rear side (− X direction side) on the base 10 illustrated in FIG. 1, a gate-shaped column 14 is disposed upright in such a manner as to straddle the movement path of the chuck table 30. On the front surface of the gate-shaped column 14, for example, a first horizontal movement mechanism 15 that reciprocates the first cutting unit 61 in a Y-axis direction orthogonal to the X-axis direction and the Z-axis direction is disposed.

For example, the first horizontal movement mechanism 15 includes a ball screw 150 having the center axis that extends in the Y-axis direction, a pair of guide rails 151 disposed in parallel to the ball screw 150, an unillustrated motor that is coupled to one end of the ball screw 150, and a movable plate 153 that has an internal nut screwed to the ball screw 150 and has a side part in slide contact with the guide rails 151. Further, when the unillustrated motor rotates the ball screw 150, the movable plate 153 is guided by the guide rails 151 and moves in the Y-axis direction in association with this, so that horizontal movement (indexing feeding) of the first cutting unit 61 disposed on the movable plate 153 with the intermediary of a first cutting-in feed mechanism 17 is executed in the Y-axis direction.

The first cutting-in feed mechanism 17 can reciprocate the first cutting unit 61 in the Z-axis direction and includes a ball screw 170 having the center axis that extends in the Z-axis direction, a pair of guide rails 171 disposed in parallel to the ball screw 170, a motor 172 coupled to the ball screw 170, and a support component 173 that supports the first cutting unit 61 and has an internal nut screwed to the ball screw 170 and a side part in slide contact with the guide rails 171. When the motor 172 rotates the ball screw 170, the support component 173 is guided by the pair of guide rails 171 and moves in the Z-axis direction. In association with this, cutting-in feeding of the first cutting unit 61 is executed in the Z-axis direction.

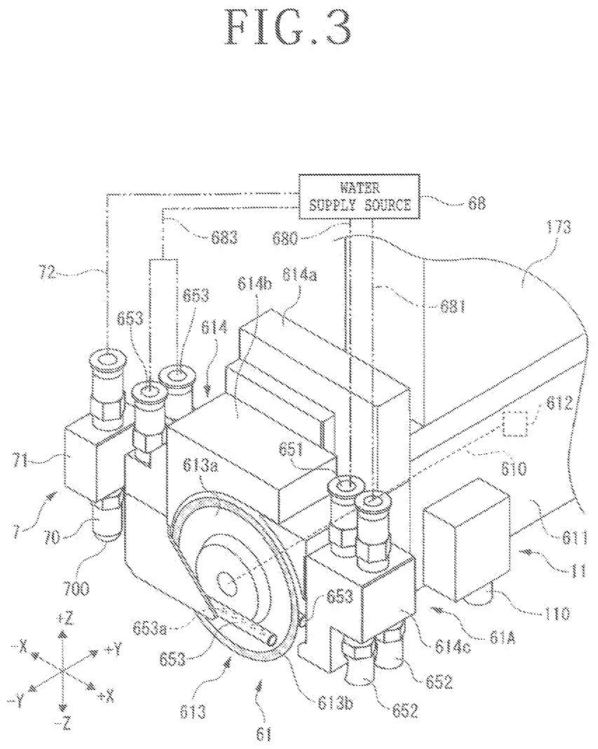

As illustrated in FIG. 3, the first cutting unit 61 includes a spindle unit 61A that rotates a spindle 610 to which an unillustrated mount on which the cutting blade 613 is mounted is coupled and a blade cover 614 that surrounds the unillustrated mount and the cutting blade 613.

The spindle unit 61A includes the spindle 610 whose axis direction is the Y-axis direction, a spindle housing 611 that is fixed to the lower end side of the support component 173 of the first cutting-in feed mechanism 17 and rotatably supports the spindle 610, and a motor 612 that rotates the spindle 610. The tip side of the spindle 610 rotatably housed in the spindle housing 611 protrudes from the inside of the spindle housing 611 toward the - Y direction side, and the unillustrated mount is mounted on this tip side.

The cutting blade 613 illustrated in FIG. 3 is a circular-ring-shaped blade of a washer type that is formed into a circular ring plate shape, has a hole into which the spindle 610 is inserted at the center, and has, at the outer circumference, a circular-ring-shaped cutting edge 613b formed by fixing diamond abrasive grains or the like by an appropriate binder.

An unillustrated fixing nut is screwed to the spindle 610 and is fastened, and the cutting blade 613 is thereby sandwiched by the unillustrated mount and fixing nut from both sides in the Y-axis direction. This provides a state in which the cutting blade 613 is sandwiched and fixed by the mount and a fixing flange 613a having a hole into which the spindle 610 is inserted and is mounted on the spindle 610, i.e. a state in which the first cutting unit 61 has been assembled as illustrated in FIGS. 1 and 3. A state in which the rotation center of the cutting blade 613 substantially corresponds with the center axis of the spindle 610 is made. Further, the cutting blade 613 rotates in association with rotational driving of the spindle 610 by the motor 612 coupled to the rear end side of the spindle 610.

The blade cover 614 that surrounds the unillustrated mount and the cutting blade 613 from the upper side includes a blade cover base part 614a and a slide cover part 614b that is disposed on the blade cover base part 614a and can slide in the X-axis direction relative to the blade cover base part 614a.

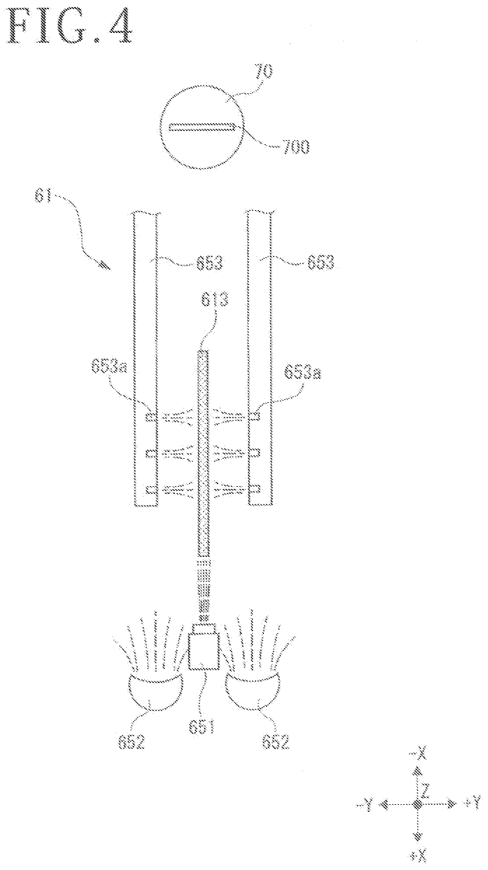

A nozzle support block 614c is disposed on the side surface of the blade cover base part 614a on the + X direction side. In the nozzle support block 614c, for example, one shower nozzle 651 that jets cutting water toward the cutting blade 613 from the outside of the cutting blade 613 in the radial direction is disposed. A water supply source 68 that can send out purified water or the like communicates with the shower nozzle 651 through a resin tube 680. As illustrated in FIG. 4, the cutting water supplied from the shower nozzle 651 to the cutting blade 613 mainly plays a role of cooling the cutting blade 613.

Further, as illustrated in FIG. 3, for example, two cutting water nozzles 652 that jet and supply the cutting water from the obliquely-upper side toward the contact part (processing point) between the cutting blade 613 and the wafer W are disposed in the nozzle support block 614c. For example, the two cutting water nozzles 652 are disposed symmetrically with each other in the Y-axis direction with the cutting blade 613 being the axis of symmetry in plan view. The water supply source 68 communicates with the cutting water nozzles 652 through a resin tube 681. As illustrated in FIG. 4, the cutting water supplied from the two cutting water nozzles 652 to the processing point mainly plays a role of cleaning up and removing cutting dust generated at the processing point from the wafer W.

The slide cover part 614b is coupled to the blade cover base part 614a with the intermediary of an unillustrated air cylinder and is capable of slide movement in the X-axis direction. Further, after the cutting blade 613 is mounted on the spindle 610, the blade cover 614 is mounted on the front surface of the spindle housing 611 on the − Y direction side, and the slide cover part 614b in an opened state is slid in the − X direction to close the blade cover 614. This allows the cutting blade 613 to be housed in an opening at substantially the center of the blade cover 614 and provides a state in which the first cutting unit 61 can cut the wafer W.

As illustrated in FIG. 3, the slide cover part 614b supports a pair of blade cooling nozzles 653 with a substantially L-shape as viewed from the − Y direction side. The blade cooling nozzles 653 pass in the slide cover part 614b to extend downward and then extend toward the + X direction side in parallel to each other in such a manner as to sandwich the lower part of the cutting blade 613. The upper end of each of the blade cooling nozzles 653 communicates with the water supply source 68 through a resin tube 683. As illustrated in FIG. 4, the pair of blade cooling nozzles 653 has plural slits 653a oriented toward the side surface of the cutting blade 613, and the cutting blade 613 is cooled and cleaned by the cutting water jetted from the slits 653a.

The edge trimming apparatus 1 illustrated in FIG. 1 includes cleaning units 7 that clean the region 300a outside the ring-shaped groove 301 in the holding surface 300 (i.e. upper surface 300) of the chuck table 30 and the upper surface 300 of the chuck table 30 including the ring-shaped groove 301. The cleaning unit 7 illustrated in FIGS. 1 and 3 includes a cleaning nozzle 70 that is mounted on the blade cover 614 and jets high-pressure water in the downward direction (− Z direction), for example. Hereinafter, the cleaning unit 7 will be defined as the cleaning unit 7 of the first embodiment including the cleaning nozzle 70.

For example, the cleaning nozzle 70 is supported by a cleaning nozzle support block 71 mounted on the side surface of the slide cover part 614b on the − X direction side. In the cleaning nozzle 70, a jet port 700 formed at the lower end thereof has a rectangular shape whose longitudinal direction is the Y-axis direction as illustrated in FIG. 4, for example. Thus, the cleaning nozzle 70 can jet cleaning water from the jet port 700 in a substantially fan shape that spreads out downward. The upper end of the cleaning nozzle 70 communicates with the water supply source 68 through a resin tube 72.

The cleaning nozzle 70 may also be connected to an unillustrated air supply source and be capable of jetting binary fluid obtained by mixing water supplied from the water supply source 68 and air supplied from the air supply source. Further, the cleaning nozzle 70 may be capable of jetting cleaning water to which ultrasonic vibrations are given.

As illustrated in FIGS. 1 and 3, near the first cutting unit 61, an alignment unit 11 that detects the position of the chamfered part Wd that should be cut in the wafer W held on the chuck table 30 is disposed. The alignment unit 11 can execute image processing such as pattern matching based on a captured image acquired by a camera 110 and detect the coordinate position of the chamfered part Wd.

On the front surface of the gate-shaped column 14 illustrated in FIG. 1, for example, a second horizontal movement mechanism 16 that reciprocates the second cutting unit 62 in the Y-axis direction is disposed. For example, the second horizontal movement mechanism 16 includes a ball screw 160 having the center axis that extends in the Y-axis direction, the pair of guide rails 151 disposed in parallel to the ball screw 160, a motor 162 coupled to the ball screw 160, and a movable plate 163 that has an internal nut screwed to the ball screw 160 and has a side part in slide contact with the guide rails 151. Further, when the motor 162 rotates the ball screw 160, the movable plate 163 is guided by the guide rails 151 and moves in the Y-axis direction in association with this, so that horizontal movement (indexing feeding) of the second cutting unit 62 disposed on the movable plate 163 with the intermediary of a second cutting-in feed mechanism 18 is executed in the Y-axis direction.

The second cutting-in feed mechanism 18 can reciprocate the second cutting unit 62 in the Z-axis direction and includes a ball screw 180 having the center axis that extends in the Z-axis direction, a pair of guide rails 181 disposed in parallel to the ball screw 180, a motor 182 coupled to the ball screw 180, and a support component 183 that supports the second cutting unit 62 and has an internal nut screwed to the ball screw 180 and a side part in slide contact with the guide rails 181. Further, when the motor 182 rotates the ball screw 180, the support component 183 is guided by the pair of guide rails 181 and moves in the Z-axis direction. In association with this, cutting-in feeding of the second cutting unit 62 is executed in the Z-axis direction.

The second cutting unit 62 is disposed opposed to the first cutting unit 61 in the Y-axis direction. The above-described first cutting unit 61 and the second cutting unit 62 are configured substantially similarly and therefore, detailed description of the second cutting unit 62 is omitted.

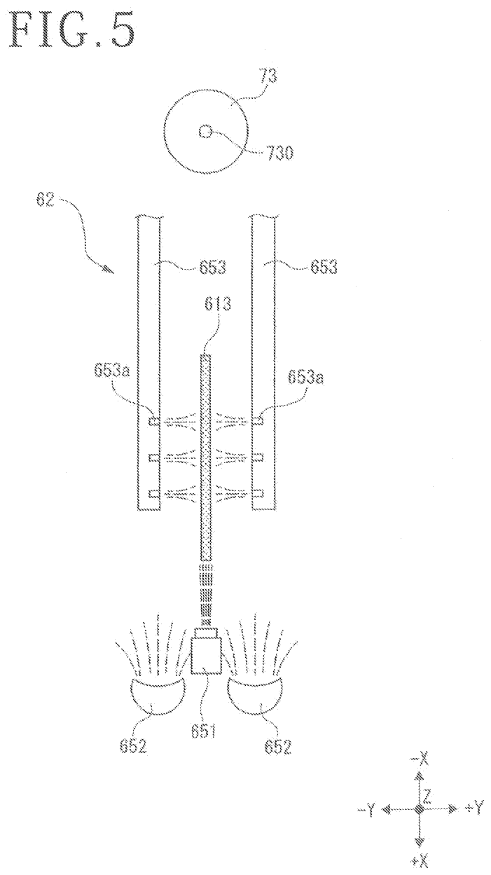

The cleaning unit 7 is disposed also on the blade cover 614 of the second cutting unit 62. The cleaning unit 7 disposed on the blade cover 614 of the second cutting unit 62 includes a cleaning nozzle 73 supported by a cleaning nozzle support block 71. In the cleaning nozzle 73, as illustrated in FIG. 5, a jet port 730 formed at the lower end thereof has a circular shape, for example. Thus, the cleaning nozzle 73 can jet cleaning water in a substantially circular column shape from the jet port 730 to the lower side. The upper end of the cleaning nozzle 73 communicates with the water supply source 68 illustrated in FIG. 3 through an unillustrated resin tube. For example, the cleaning nozzle 73 may also be connected to an unillustrated air supply source and be capable of jetting binary fluid obtained by mixing water supplied from the water supply source 68 and air supplied from the air supply source. Further, the cleaning nozzle 73 may be capable of jetting cleaning water to which ultrasonic vibrations are added. The cleaning nozzle 70 may be disposed on the second cutting unit 62, and the cleaning nozzle 73 may be disposed on the first cutting unit 61.

The shower nozzle 651 illustrated in FIG. 3, the two cutting water nozzles 652, the pair of blade cooling nozzles 653, the cleaning nozzle 70, and the cleaning nozzle 73 each come into a state in which it communicates with the water supply source 68 and a state in which it does not communicate with the water supply source 68 through switching of opening and closing of an unillustrated open-close valve that is disposed in a respective one of the resin tubes that communicate with them.

A description will be made below of the case in which, in the edge trimming apparatus 1 illustrated in FIG. 1, the region 300a outside the ring-shaped groove 301 in the upper surface 300 (holding surface 300) of the chuck table 30 and the upper surface 300 of the chuck table 30 including the ring-shaped groove 301 are cleaned and thereafter, the bonded wafer W1 is held by the cleaned chuck table 30, and edge trimming is annularly executed on the chamfered part Wd of the circumferential part of the wafer W.

In the cleaning of the chuck table 30, first, the chuck table 30 that does not hold the bonded wafer W1 illustrated in FIG. 1 is moved in the X-axis direction by the cutting feed mechanism 13, and the chuck table 30 is positioned below the cleaning unit 7 disposed on the blade cover 614 of the first cutting unit 61 and the cleaning unit 7 disposed on the blade cover 614 of the second cutting unit 62.

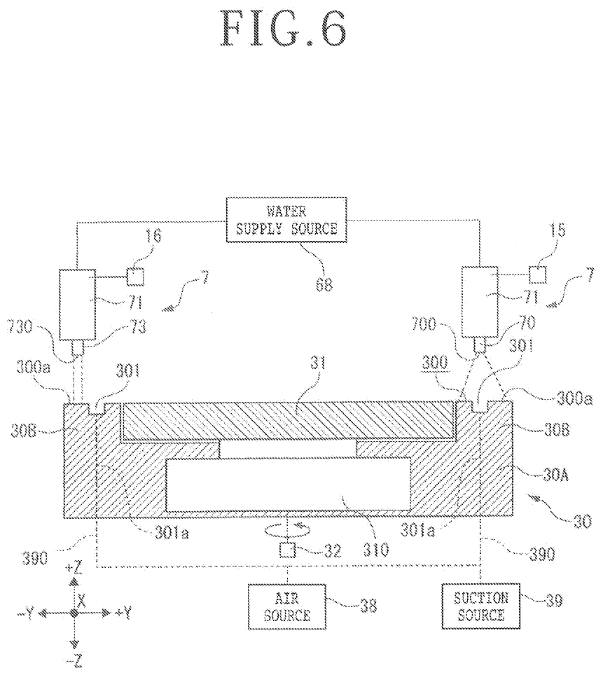

An unillustrated control unit that executes control of the overall apparatus of the edge trimming apparatus 1 grasps the center position of the chuck table 30 and can therefore also grasp the position of the ring-shaped groove 301 separate from this center position outward in the radial direction by a predetermined distance. Then, for example, based on the center position of the chuck table 30, the first horizontal movement mechanism 15 moves the cleaning nozzle 70 of the cleaning unit 7 disposed on the blade cover 614 in the Y-axis direction together with the first cutting unit 61, to cause the center of the groove width of the ring-shaped groove 301 to substantially correspond with the center of the cleaning nozzle 70. As a result, as illustrated in FIG. 6, the landing area of high-pressure cleaning water jetted from the cleaning nozzle 70 in such a manner as to spread downward in a substantially fan shape as viewed from the near side of the plane of paper (+ X direction side) is positioned to the ring-shaped groove 301 and the holding surface 300 of the chuck table 30.

Further, for example, based on the center position of the chuck table 30, the second horizontal movement mechanism 16 moves the cleaning nozzle 73 of the cleaning unit 7 disposed on the blade cover 614 in the Y-axis direction together with the second cutting unit 62 to position the center of the cleaning nozzle 73 that jets the cleaning water downward in a circular column shape to the region 300a outside the ring-shaped groove 301.

Subsequently, the first cutting-in feed mechanism 17 illustrated in FIG. 1 moves the cleaning nozzle 70 in the Z-axis direction to position it at a proper height, and the second cutting-in feed mechanism 18 moves the cleaning nozzle 73 in the Z-axis direction to position it at a proper height.

In this state, the water supply source 68 illustrated in FIG. 6 supplies the high-pressure water to the cleaning nozzle 70. As illustrated in FIG. 6, the cleaning water is jetted to spread downward in a substantially fan shape from the jet port 700 of the cleaning nozzle 70, and mainly, cutting dust adhering to the groove bottom and sidewall of the ring-shaped groove 301, cutting dust adhering to the holding surface 300 (upper surface 300), and so forth are cleaned up and removed by this cleaning water over a wide range. Further, the water supply source 68 supplies the high-pressure water to the cleaning nozzle 73. As a result, as illustrated in FIG. 6, the cleaning water is jetted downward in a circular column shape from the jet port 730 of the cleaning nozzle 73, and the region 300a outside the ring-shaped groove 301 in the holding surface 300 is intensively cleaned by this cleaning water as pinpoint cleaning. Thus, cutting dust and so forth adhering to the region 300a are removed.

Further, the table rotation mechanism 32 rotates the chuck table 30 at a predetermined rotation speed. In association with this, the whole circumference of the ring-shaped groove 301 and the whole circumference of the holding surface 300 are evenly cleaned by the cleaning water jetted from the cleaning nozzle 70 and the cleaning water jetted from the cleaning nozzle 73.

After the cleaning of the whole circumference of the ring-shaped groove 301 and the cleaning of the whole circumference of the holding surface 300, particularly, the intensive cleaning of the whole circumference of the region 300a outside the ring-shaped groove 301, have been executed for a predetermined period of time, the water supply source 68 stops the supply of water to the cleaning nozzle 70 and the cleaning nozzle 73. Thereafter, for example, the chuck table 30 is dried by rotational drying based on rotation or through ejection of air from the cleaning nozzle 70 or 73 that communicates with an unillustrated air source.

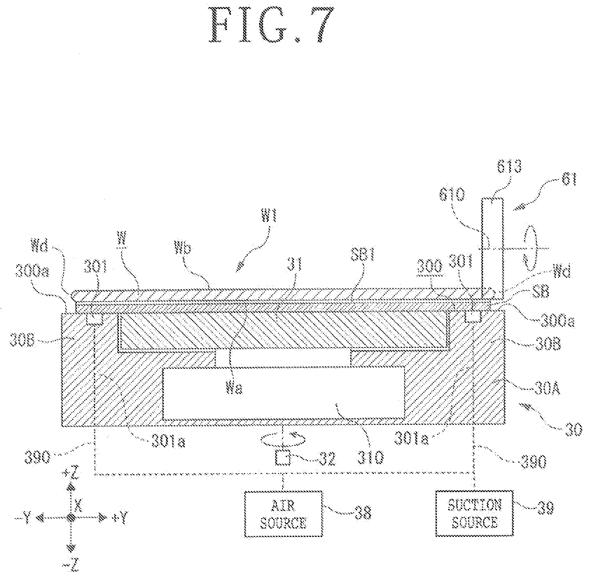

Subsequently, edge trimming processing of the chamfered part Wd of the wafer W illustrated in FIG. 1 is started. First, in such a manner that the center of the wafer W substantially corresponds with the center of the holding surface 300 of the chuck table 30, the bonded wafer W1 is placed on the holding surface 300 to close the ring-shaped groove 301, with the substrate SB oriented downward. Then, a suction force generated through driving of the suction source 39 illustrated in FIG. 7 passes through the suction holes 301a and the ring-shaped groove 301 and is transmitted to the holding surface 300, and the chuck table 30 holds under suction the circumferential region of the substrate SB stuck to the lower surface Wa (front surface Wa) of the wafer W on the holding surface 300. Further, the bonded wafer W1 comes into a state of being placed on the upper surface of the rising-lowering table 31.

The cutting feed mechanism 13 illustrated in FIG. 1 moves the chuck table 30 in the X-axis direction. In addition, for example, the first horizontal movement mechanism 15 moves the camera 110 of the alignment unit 11 in the Y-axis direction, and the chuck table 30 is positioned to a predetermined position so that the chamfered part Wd formed at the circumferential edge of the wafer W may fall within the imaging region of the camera 110. Imaging of the chamfered part Wd of the wafer W is executed by the camera 110, and the alignment unit 11 decides the position of the edge coordinates of the chamfered part Wd of the wafer W, based on the captured image.

For example, after the position of the edge coordinates of the chamfered part Wd of the wafer W is detected in the above-described manner, the bonded wafer W1 held by the chuck table 30 is positioned below the cutting blade 613 of the first cutting unit 61, for example. Then, based on the position of the edge coordinates of the chamfered part Wd of the wafer W obtained by the edge alignment, the first horizontal movement mechanism 15 moves the first cutting unit 61 in the Y-axis direction and positions the cutting blade 613 to a position separate from the chamfered part Wd of the wafer W inward in the radial direction by a predetermined distance as illustrated in FIG. 7. Specifically, for example, the cutting blade 613 is positioned in such a manner that approximately ⅔ of the lower end surface of the cutting blade 613 comes into contact with the chamfered part Wd of the wafer W.

Subsequently, by rotating the spindle 610 at high speed in the anticlockwise direction as viewed from the + Y direction side, the cutting blade 613 fixed to the spindle 610 is rotated at high speed in the anticlockwise direction as viewed from the + Y direction side. Moreover, the first cutting-in feed mechanism 17 illustrated in FIG. 1 lowers the first cutting unit 61 and causes the cutting blade 613 to cut into the wafer W by a predetermined depth from a back surface Wb of the wafer W. The cutting-in depth of the cutting blade 613 is a cutting-in depth with which the chamfered part Wd is completely cut and the cutting blade 613 does not reach the adhesive SB1 or slightly cuts into the adhesive SB1, for example. After the cutting-in feeding of the cutting blade 613 is executed to the predetermined height position, the chuck table 30 is rotated by 360 degrees in the anticlockwise direction as viewed from the + Z direction side, with the cutting blade 613 kept rotating. The whole circumference of the chamfered part Wd of the wafer W is thereby cut. Dual edge trimming of the chamfered part Wd of the wafer W may be executed by the first cutting unit 61 and the second cutting unit 62.

During the edge trimming of the chamfered part Wd of the wafer W, the cutting water is supplied to the cutting blade 613 from the outside of the cutting blade 613 in the radial direction by the shower nozzle 651 illustrated in FIG. 3 and FIG. 4, and mainly, cooling of the cutting blade 613 is executed. Further, the cutting water is supplied to the contact part between the cutting blade 613 and the wafer W by the two cutting water nozzles 652, and mainly, cooling of the contact part and cleaning removal of cutting dust generated at the contact part are executed by this cutting water. Further, the cutting water is supplied to the cutting blade 613 from the thickness direction of the cutting blade 613 (Y-axis direction) by the pair of blade cooling nozzles 653, and cooling of the cutting blade 613 is executed.

As described above, the edge trimming apparatus 1 according to the present invention includes the cleaning unit 7 that cleans the region 300a outside the ring-shaped groove 301 in the upper surface 300 of the chuck table 30 and the upper surface 300 of the chuck table 30 including the ring-shaped groove 301. The cleaning unit 7 is positioned to the region 300a and the upper surface 300 of the chuck table 30 including the ring-shaped groove 301, and the chuck table 30 is rotated by the table rotation mechanism 32 to clean the region 300a and the upper surface 300 of the chuck table 30 including the ring-shaped groove 301. The bonded wafer W1 can thereby be flatly held by the chuck table 30 that has been cleaned and has an upper surface 300 to which cutting dust is not adhered. Therefore, the depth of the recess formed by edge trimming processing of the chamfered part Wd at the circumferential edge of the wafer W can be made constant. Further, because the inside of the ring-shaped groove 301 can be cleaned, it becomes possible to prevent the lowering of the suction force of the chuck table 30 that possibly occurs due to clogging of the ring-shaped groove 301 with cutting dust.

In the edge trimming apparatus 1 according to the present invention, the cleaning units 7 of the first embodiment include the cleaning nozzles 70 and 73 that are mounted on the blade cover 614 and jet high-pressure water in the downward direction. The landing area of the high-pressure water jetted from the cleaning nozzle 70 is positioned to the region 300a outside the ring-shaped groove 301 in the upper surface 300 of the chuck table 30 and the upper surface 300 of the chuck table 30 including the ring-shaped groove 301 by the first horizontal movement mechanism 15, and cleaning is executed while the chuck table 30 is rotated. The bonded wafer W1 can thereby be flatly held by the chuck table 30 that has been cleaned and has an upper surface 300 to which processing dust is not adhered. Therefore, the depth of the recess formed by the edge trimming processing of the chamfered part Wd of the wafer W can be made constant. Further, because the inside of the ring-shaped groove 301 can be cleaned, it becomes possible to prevent the lowering of the suction force of the chuck table 30 that possibly occurs due to clogging of the ring-shaped groove 301 with processing dust.

Further, for example, in the edge trimming apparatus 1 including the first cutting unit 61 and the second cutting unit 62 as in the present first embodiment in such a manner that the two cutting units are opposed to each other, the first cutting unit 61 includes the cleaning nozzle 70 as the cleaning unit 7, and the second cutting unit 62 includes the cleaning nozzle 73 as the cleaning unit 7, for example. Further, the cleaning areas of the respective cleaning nozzles can be made different to change the role in the cleaning. For example, one cleaning nozzle 73 is used as a nozzle dedicated to intensive cleaning for the region 300a outside the ring-shaped groove 301 in the upper surface 300 of the chuck table 30 and is caused to jet high-pressure cleaning water in a circular column shape, and the cleaning water is caused to reach the region 300a. Meanwhile, the other cleaning nozzle 70 is used as a nozzle dedicated to cleaning of a wide range of the upper surface 300 of the chuck table 30 and the ring-shaped groove 301 and is caused to jet the high-pressure cleaning water in a substantially fan shape. This enables cleaning of the ring-shaped groove 301 and the upper surface 300 of the chuck table 30 more efficiently in such a manner that no place is left uncleaned.

The water supply source 68 including a pump or the like does not have to be of a type that can send out high-pressure water to the cleaning nozzles 70 and 73, for example. The cleaning nozzles 70 and 73 may be made to communicate also with an air supply source in addition to the water supply source 68, and air may be mixed with water in each nozzle, for example, to cause binary fluid to be jetted from each jet port, and the pressure of water droplets that impinge on landing points in the cleaning area may be set to high pressure by the pressure of the air.

### Second Embodiment

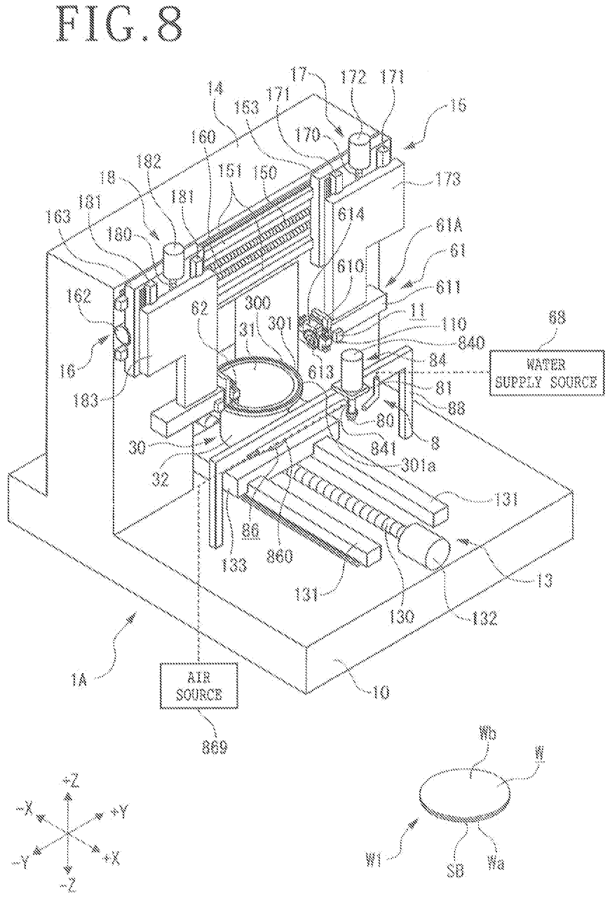

An edge trimming apparatus 1A of a second embodiment illustrated in FIG. 8 is an apparatus obtained by changing some of constituent elements of the edge trimming apparatus 1 of the first embodiment illustrated in FIG. 1. The part different from the configuration of the edge trimming apparatus 1 of the first embodiment in the edge trimming apparatus 1A of the second embodiment will be described below.

For example, the edge trimming apparatus 1A includes a cleaning unit 8 of the second embodiment including a sponge 80 illustrated in FIG. 8 and a nozzle 81 for sponge that supplies cleaning water to the sponge 80, in place of the cleaning unit 7 including the cleaning nozzle 70 in the edge trimming apparatus 1 of the first embodiment.

For example, a support bridge 88 is dispose upright on the base 10 of the edge trimming apparatus 1A in such a manner as to straddle the movement path of the chuck table 30, and the cleaning unit 8 is attached to the support bridge 88. The cleaning unit 8 may be capable of being reciprocated on the support bridge 88 in the Y-axis direction by an unillustrated slider, for example. A jet port of the nozzle 81 for sponge is opened toward the sponge 80 and communicates with the water supply source 68.

The kind of sponge 80 is not particularly limited and, for example, a polyvinyl alcohol (PVA) sponge or the like is used. The sponge 80 is formed into a circular column shape, for example, and is allowed to move up and down in the Z-axis direction by a sponge raising-lowering mechanism 84 attached to the support bridge 88. The shape of the sponge 80 is not limited to the present example.

The sponge raising-lowering mechanism 84 is an air cylinder, for example, and includes a tubular cylinder tube 840 internally having an unillustrated piston and a piston rod 841 that is inserted in the cylinder tube 840 and has the upper end side attached to the piston. Further, the sponge 80 is removably attached to the lower end side of the piston rod 841.

For example, an air nozzle 86 that extends in the Y-axis direction is attached to the support bridge 88. The air nozzle 86 has a length equal to or larger than the outer diameter of the chuck table 30, for example, and has plural slits 860 oriented downward in the side surface thereof. Further, the air nozzle 86 can dry the holding surface 300 of the chuck table 30 and the inside of the ring-shaped groove 301 by compressed air jetted from the slits 860. The air nozzle 86 includes a compressor or like and communicates with an air source 869 that can supply the compressed air through a resin tube or the like.

A description will be made below of the case in which, in the edge trimming apparatus 1A illustrated in FIG. 8, the ring-shaped groove 301 of the chuck table 30 and the region 300a outside the ring-shaped groove 301 in the upper surface of the chuck table 30 are cleaned and thereafter, the bonded wafer W1 is held by the cleaned chuck table 30, and edge trimming is annularly executed on the chamfered part Wd of the circumferential part of the wafer W.

In the cleaning of the chuck table 30, first, the chuck table 30 that does not hold the bonded wafer W1 illustrated in FIG. 8 is moved in the X-axis direction by the cutting feed mechanism 13, and the chuck table 30 is positioned below the sponge 80 of the cleaning unit 8. The sponge 80 is thereby positioned to substantially traverse, in the groove width direction, the region 300a outside the ring-shaped groove 301 in the upper surface 300 of the chuck table 30 and the upper surface 300 of the chuck table 30 including the ring-shaped groove 301.

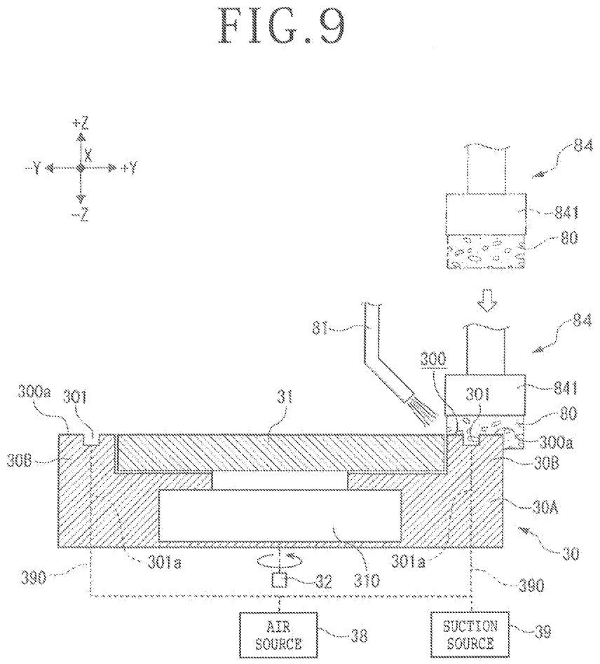

Subsequently, the sponge raising-lowering mechanism 84 illustrated in FIG. 8 lowers the sponge 80 and brings the sponge 80 deformed as illustrated in FIG. 9 into contact with the groove bottom of the ring-shaped groove 301 of the chuck table 30 and the region 300a outside the ring-shaped groove 301 in the holding surface 300.

Further, the water supply source 68 sends out the cleaning water to the nozzle 81 for sponge, and the sponge 80 absorbs the cleaning water jetted from the nozzle 81 for sponge. This causes the sponge 80 to swell and have elasticity. The sponge 80 may be one that does not swell when absorbing the cleaning water. Further, the cleaning water may directly be supplied from the nozzle 81 for sponge to the ring-shaped groove 301 and the region 300a of the chuck table 30.

Further, in association with rotation of the chuck table 30 at a predetermined rotation speed by the table rotation mechanism 32, the whole circumference of the ring-shaped groove 301 and the whole circumference of the holding surface 300 are cleaned by the sponge 80 supplied with the cleaning water, and adhering cutting dust and so forth are removed.

After the cleaning of the whole circumference of the ring-shaped groove 301 and the whole circumference of the holding surface 300, particularly, intensive cleaning of the whole circumference of the region 300a outside the ring-shaped groove 301, have been executed for a predetermined period of time, the water supply source 68 stops the supply of water to the nozzle 81 for sponge. Further, the sponge raising-lowering mechanism 84 raises the sponge 80 to separate it from the chuck table 30.

Next, the chuck table 30 moves in the X-axis direction below the air nozzle 86 by the cutting feed mechanism 13 illustrated in FIG. 1. In addition, high-pressure air is made to blow from the air nozzle 86 toward the holding surface 300 of the chuck table 30. As a result, the cleaning water adhering to the holding surface 300 and the ring-shaped groove 301 is blown off by the air, and the holding surface 300 and the ring-shaped groove 301 are dried. For example, the chuck table 30 may be dried by rotational drying based on rotation or through ejection of air from the nozzle 81 for sponge that communicates with an unillustrated air source.

Subsequently, edge trimming processing of the wafer W is started. The edge trimming of the wafer W is executed similarly to the case in the edge trimming apparatus 1 of the first embodiment described earlier.

In the edge trimming apparatus 1A of the second embodiment according to the present invention, the cleaning unit 8 includes the sponge 80 and the nozzle 81 for sponge that supplies cleaning water to the sponge 80. The sponge 80 is positioned to the region 300a outside the ring-shaped groove 301 in the upper surface 300 of the chuck table 30 and the upper surface 300 of the chuck table 30 including the ring-shaped groove 301, and cleaning is executed by the sponge 80 to which the cleaning water is supplied from the nozzle 81 for sponge. The bonded wafer W1 can thereby be flatly held by the chuck table 30 that has been cleaned and has the upper surface 300 to which processing dust is not adhered. Therefore, the depth of the recess formed by edge trimming processing of the chamfered part Wd at the circumferential edge of the wafer W can be made constant. Further, because the inside of the ring-shaped groove 301 can be cleaned, it becomes possible to prevent the lowering of the suction force of the chuck table 30 that possibly occurs due to clogging of the ring-shaped groove 301 with cutting dust.

The edge trimming apparatus according to the present invention is not limited to the above-described first and second embodiments. Further, the respective configurations and so forth of the apparatuses illustrated in the accompanying drawings are also not limited thereto, and changes can be made as appropriate in a range in which effects of the present invention can be exerted. For example, the edge trimming apparatus 1 of the first embodiment may include the air nozzle 86 of the edge trimming apparatus 1A of the second embodiment.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An edge trimming apparatus comprising:
a chuck table that has a ring-shaped groove with an outer diameter smaller than an outer diameter of a wafer and causes the ring-shaped groove to communicate with a suction source to hold under suction a lower surface of the wafer by the ring-shaped groove;
a table rotation mechanism that rotates the chuck table;
a cutting unit that rotates a spindle on which a cutting blade is mounted and annularly cuts a circumferential part of the wafer held by the chuck table; and
a cleaning unit that cleans a region outside the ring-shaped groove in an upper surface of the chuck table and the upper surface of the chuck table including the ring-shaped groove,
wherein
the cleaning unit is positioned to the region outside the ring-shaped groove in the upper surface of the chuck table and the upper surface of the chuck table including the ring-shaped groove, and the chuck table is rotated by the table rotation mechanism, to clean the region outside the ring-shaped groove in the upper surface of the chuck table and the upper surface of the chuck table including the ring-shaped groove.

2. The edge trimming apparatus according to claim 1, further comprising:
a horizontal movement mechanism that moves the cutting unit in a center axis direction of the spindle,
wherein
the cutting unit includes a spindle unit that rotates the spindle to which a mount on which the cutting blade is mounted is coupled and a blade cover that surrounds the mount and the cutting blade,
the cleaning unit includes a cleaning nozzle that is mounted on the blade cover and jets high-pressure water in a downward direction, and
a landing area of the high-pressure water jetted from the cleaning nozzle is positioned to the region outside the ring-shaped groove in the upper surface of the chuck table and the upper surface of the chuck table including the ring-shaped groove by the horizontal movement mechanism, and cleaning is executed.

3. The edge trimming apparatus according to claim 1, wherein
the cleaning unit includes a sponge and a nozzle for sponge that supplies cleaning water to the sponge, and
the sponge is positioned to the region outside the ring-shaped groove in the upper surface of the chuck table and the upper surface of the chuck table including the ring-shaped groove, and cleaning is executed by the sponge to which the cleaning water is supplied from the nozzle for sponge.
